(19) United States
(12) Patent Application Publication
(10) Pub. No.: US 2010/0053865 A1
(43) Pub. Date: Mar. 4, 2010

(54) SYSTEM AND METHOD TO SUPPORT EXTERNAL DEVICES IN RELATION TO A SERVER RACK

(75) Inventors: Mahesh Vellore Chandramouli, Bangalore (IN); Krishnaprasad K., Bangalore (IN); Sumitha Bennet, Malleshpalya (IN)

Correspondence Address: LARSON NEWMAN & ABEL, LLP, 5914 WEST COURTYARD DRIVE, SUITE 200, AUSTIN, TX, 78730, US

(73) Assignee: DELL PRODUCTS, LP, Round Rock, TX (US)

(21) Appl. No.: 12/249,596

(22) Filed: Oct. 10, 2008

(30) Foreign Application Priority Data
Aug. 28, 2008 (IN) 2039/DEL/2008

(51) Int. Cl. H05K 5/00; H01S 4/00

(52) U.S. Cl. 361/679.02; 29/592.1

(57) ABSTRACT

A system to support external devices in relation to a server rack includes a server rack chassis having a plurality of sides. Each side has a pair of substantially vertical edges extending along a height of the server rack chassis. The system also includes a rail member having a first end coupled to the server rack chassis. The rail member is substantially parallel to the substantially vertical edges when the first end of the rail member is coupled to the server rack chassis. The system also includes a tray having a first aperture adapted to slidably receive a second end of the rail member.

### CROSS REFERENCE TO RELATED APPLICATIONS

This application claims priority under 35 U.S.C. §119 to Indian Patent Application No. 2039/DEL/2008, entitled “SYSTEM AND METHOD TO SUPPORT EXTERNAL DEVICES IN RELATION TO A SERVER RACK,” filed on Aug. 28, 2008.

### FIELD OF THE DISCLOSURE

This disclosure relates generally to methods and systems to support external devices in relation to a server rack.

### DESCRIPTION OF THE RELATED ART

As the value and use of information continues to increase, individuals and businesses seek additional ways to process and store information. One option is an information handling system. An information handling system generally processes, compiles, stores, and/or communicates information or data for business, personal, or other purposes. Because technology and information handling needs and requirements can vary between different applications, information handling systems can also vary regarding what information is handled, how the information is handled, how much information is processed, stored, or communicated, and how quickly and efficiently the information can be processed, stored, or communicated. The variations in information handling systems allow for information handling systems to be general or configured for a specific user or specific use such as financial transaction processing, airline reservations, enterprise data storage, or global communications. In addition, information handling systems can include a variety of hardware and software components that can be configured to process, store, and communicate information and can include one or more computer systems, data storage systems, and networking systems.

### BRIEF DESCRIPTION OF THE DRAWINGS

Skilled artisans appreciate that elements in the figures are illustrated for simplicity and clarity and have not necessarily been drawn to scale. For example, the dimensions of some of the elements in the figures may be exaggerated or minimized relative to other elements to help to improve understanding of embodiments of the disclosed apparatus. Embodiments incorporating teachings of the present disclosure are illustrated and described with respect to the drawings presented herein.

FIG. 1 is a diagram illustrating a particular embodiment of a system to support external devices in relation to a server rack;

FIG. 2 is a diagram illustrating a second particular embodiment of a system to support external devices in relation to a server rack;

FIG. 3 is a diagram illustrating particular embodiments of aspects of a system to support external devices in relation to a server rack;

FIG. 4 is a diagram illustrating additional particular embodiments of aspects of a system to support external devices in relation to a server rack; and

FIG. 5 is a flow diagram illustrating a particular embodiment of a method of supporting external devices in relation to a server rack.

The use of the same reference symbols in different figures indicates similar or identical items.

### DETAILED DESCRIPTION

The following description in combination with the figures is provided to assist in understanding the teachings disclosed herein. The following discussion will focus on specific implementations and embodiments of the teachings. This focus is provided to assist in describing the teachings and should not be interpreted as a limitation on the scope or applicability of the teachings. However, other teachings can certainly be utilized in this application. The teachings can also be utilized in other applications and with several different types of architectures such as distributed computing architectures, client/server architectures, or middleware server architectures and associated components.

For purposes of this disclosure, an information handling system can include any instrumentality or aggregate of instrumentalities operable to compute, classify, process, transmit, receive, retrieve, originate, switch, store, display, manifest, detect, record, reproduce, handle, or use any form of information, intelligence, or data for business, scientific, control, entertainment, or other purposes. For example, an information handling system can be a personal computer, a PDA, a consumer electronic device, a network server or storage device, a switch router, wireless router, or other network communication device, or any other suitable device and can vary in size, shape, performance, functionality, and price. The information handling system can include memory (volatile (e.g. random access memory, etc.), nonvolatile (read only memory, flash memory etc.) or any combination thereof), one or more processing resources, such as a central processing unit (CPU), hardware or software control logic, or any combination thereof. Additional components of the information handling system can include one or more storage devices, one or more communications ports for communicating with external devices as well as various input and output (I/O) devices, such as a keyboard, a mouse, a video display, or any combination thereof. The information handling system can also include one or more buses operable to transmit communications between the various hardware components.

Although referred to as a “device,” the device may be configured as hardware, firmware, software, or any combination thereof For example, the device may be hardware such as, for example, an integrated circuit (such as an Application Specific Integrated Circuit (ASIC), a Field Programmable Gate Array (FPGA), a structured ASIC, or a device embedded on a larger chip), a card (such as a Peripheral Component Interface (PCI) card, a PCI-express card, a Personal Computer Memory Card International Association (PCMCIA) card, or other such expansion card), or a system (such as a motherboard, a system-on-a-chip (SoC), or a stand-alone device). Similarly, the device could be firmware (such as any software running on an embedded device, a Pentium class or PowerPC™ brand processor, or other such device) or software (such as any software capable of operating in the relevant environment). The device could also be a combination of any of the foregoing examples of hardware, firmware, or software.

Devices or programs that are in communication with one another need not be in continuous communication with each other unless expressly specified otherwise. In addition, devices or programs that are in communication with one another may communicate directly or indirectly through one or more intermediaries.

Embodiments discussed below describe, in part, distributed computing solutions that manage all or part of a communicative interaction between network elements. In this context, a communicative interaction may be intending to send information, sending information, requesting information, receiving information, receiving a request for information, or any combination thereof. As such, a communicative interaction could be unidirectional, bi-directional, multi-directional, or any combination thereof. In some circumstances, a communicative interaction could be relatively complex and involve two or more network elements. For example, a communicative interaction may be “a conversation” or series of related communications between a client and a server—each network element sending and receiving information to and from the other. Whatever form the communicative interaction takes, the network elements involved need not take any specific form. A network element may be a node, a piece of hardware, software, firmware, middleware, some other component of a computing system, or any combination thereof.

In the description below, a flow-charted technique may be described in a series of sequential actions. The sequence of the actions and the party performing the steps may be freely changed without departing from the scope of the teachings. Actions may be added, deleted, or altered in several ways. Similarly, the actions may be re-ordered or looped. Further, although processes, methods, algorithms or the like may be described in a sequential order, such processes, methods, algorithms, or any combination thereof may be operable to be performed in alternative orders. Further, some actions within a process, method, or algorithm may be performed simultaneously during at least a point in time (e.g., actions performed in parallel), can also be performed in whole, in part, or any combination thereof.

As used herein, the terms “comprises,” “comprising,” “includes, ” “including,” “has,” “having” or any other variation thereof, are intended to cover a non-exclusive inclusion. For example, a process, method, article, or apparatus that comprises a list of features is not necessarily limited only to those features but may include other features not expressly listed or inherent to such process, method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” is employed to describe elements and components described herein. This is done merely for convenience and to give a general sense of the scope of the invention. This description should be read to include one or at least one and the singular also includes the plural, or vice versa, unless it is clear that it is meant otherwise. For example, when a single device is described herein, more than one device may be used in place of a single device. Similarly, where more than one device is described herein, a single device may be substituted for that one device.

Unless otherwise defined, all technical and scientific terms used herein have the same meaning as commonly understood by one of ordinary skill in the art to which this invention belongs. Although methods and materials similar or equivalent to those described herein can be used in the practice or testing of embodiments of the present invention, suitable methods and materials are described below. All publications, patent applications, patents, and other references mentioned herein are incorporated by reference in their entirety, unless a particular passage is cited. In case of conflict, the present specification, including definitions, will control. In addition, the materials, methods, and examples are illustrative only and not intended to be limiting.

To the extent not described herein, many details regarding specific materials, processing acts, and circuits are conventional and may be found in textbooks and other sources within the computing, electronics, and software arts.

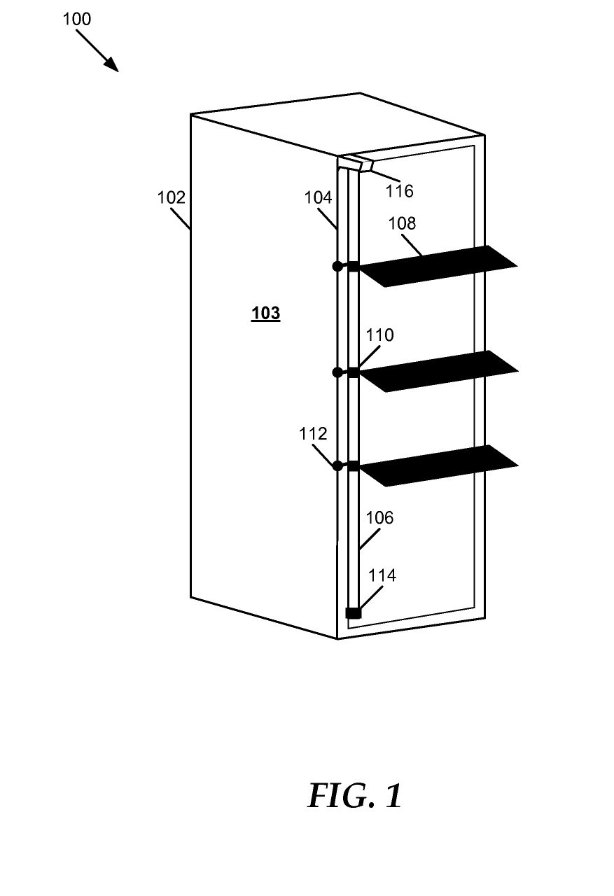

FIG. 1 illustrates a particular embodiment of a system 100 to support external devices in relation to a server rack. The system 100 includes a server rack chassis 102 adapted to receive a plurality of servers. The server rack chassis 102 includes a plurality of sides 103, where each side 103 has a pair of substantially vertical edges 104 that extend along a height of the server rack chassis 102. The system 100 also includes a rail member 106 coupled to the server rack chassis 102. In one embodiment, the rail member 106 is coupled to the server chassis 102 via an extension 116 that is coupled to or integrated with the server rack chassis 102. The rail member 106 is substantially parallel to the substantially vertical edge 104 when the rail member 106 is coupled to the server rack chassis 102.

Further, the system 100 includes one or more trays 108. Each tray 108 comprises a shelf portion bounded by a plurality of edges and includes an aperture adapted to slidably receive an end of the rail member 106. In an illustrative embodiment, a tray 108 can include a ring portion 110 coupled to or integrated with at least one edge of the tray 108, where the ring portion 110 bounds the aperture. For instance, an end of the rail member 106 can be coupled to the extension 116, and the ring 110 can be adapted to slide along the rail member 106 after receiving another end of the rail member 106 that is distal from the extension 116. A knob 114 or other element sized larger than the first aperture of the tray 108 can be coupled to the distal end of the rail member 106 to prevent each tray 108 from unintentionally sliding off the distal end of the rail member 106. The knob 114 can be removed from the distal end of the rail member 106 to allow a tray 108 to be moved onto, or to be removed from, the rail member 106.

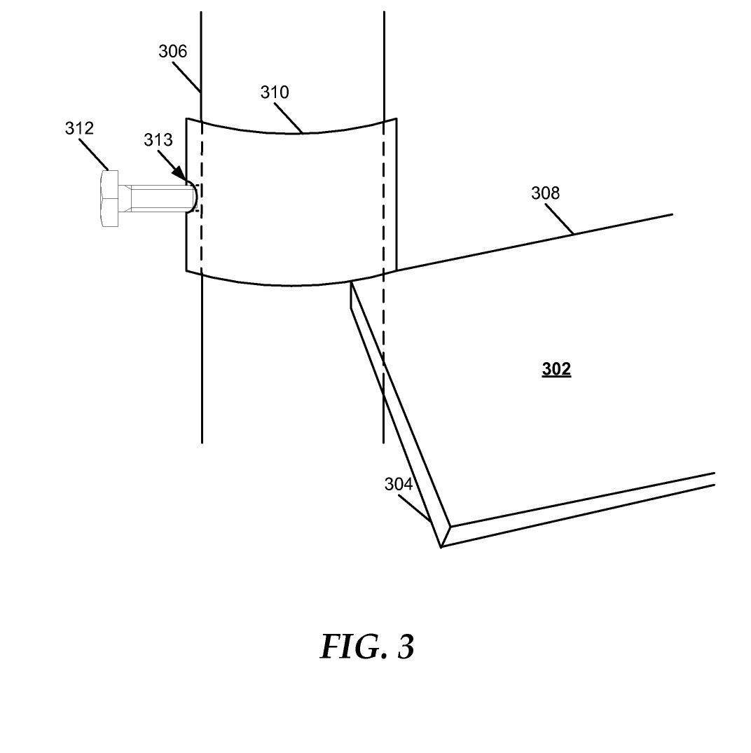

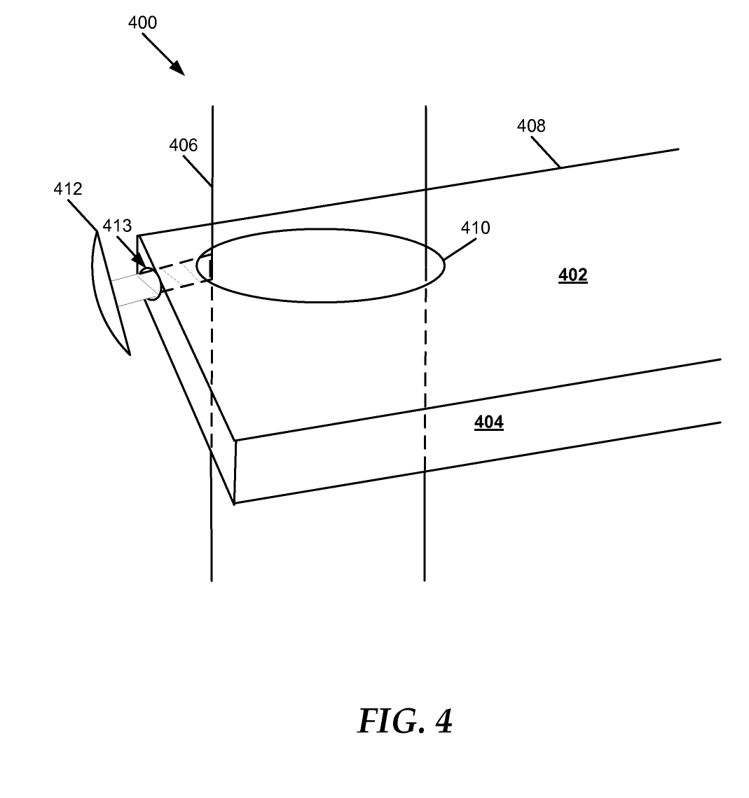

In addition, each tray 108 can include an additional aperture that is adapted to receive a locking element 112, such as an adjustable screw. The additional aperture can communicate with the aperture that slides along the rail member 106, such that the locking element 112 can be tightened against the rail member 106 to hold the tray 108 at a particular position along the rail member 106. In one embodiment, the additional aperture can be substantially perpendicular to the aperture that slides along the rail member 106. The locking element 112 can also be loosened to unsecure the tray 108 from its position, such that it can be moved to a different position along the rail member 106 or removed from the rail member 106. Each tray 108 is adapted to support an external device coupled to one or more servers housed in the server rack chassis 102 when the tray 108 is held at a position along the rail member 106. Examples of external devices include an external CD drive, an external DVD drive, an external floppy drive, an external hard drive, an input device, an output device, another external device, or any combination thereof. Particular embodiments of the trays 108 are illustrated further in FIGS. 3 and 4.

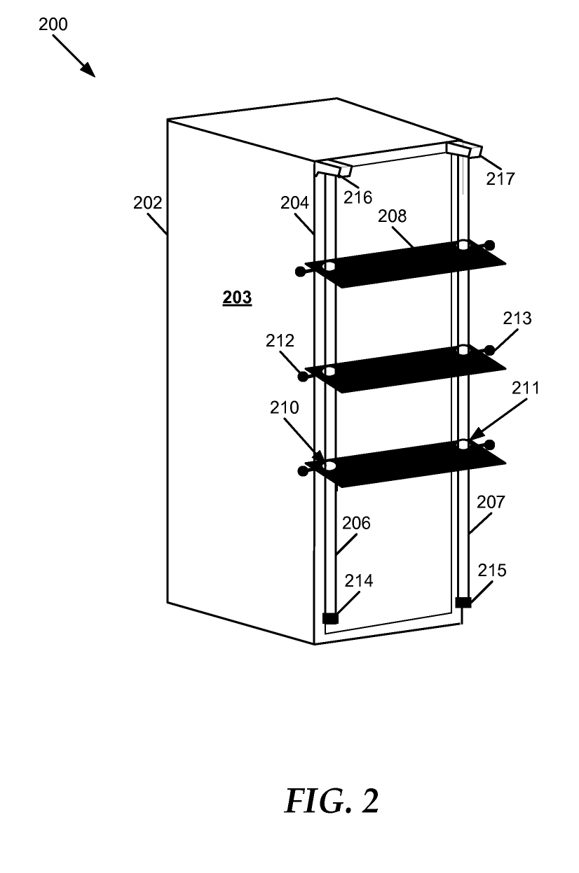

FIG. 2 illustrates a second particular embodiment of a system 200 to support external devices in relation to a server rack. The system 200 includes a server rack chassis 202 adapted to receive a plurality of servers. The server rack chassis 202 includes a plurality of sides 203, where each side 203 has a pair of substantially vertical edges 204 that extend along a height of the server rack chassis 202. The system 200 also includes a rail member 206 coupled to the server rack chassis 202. In the embodiment shown in FIG. 2, the system 200 can include an additional rail member 207. In one embodiment, the rail members 206, 207 can be coupled to extensions 216, 217 that are coupled to or integrated with the top of a side of the server rack chassis 202. The rail members 206, 207 are substantially parallel to the substantially vertical edges 204 when the rail members 206, 207 are coupled to the server rack chassis 204.

Further, the system 200 includes one or more trays 208. Each tray 208 comprises a shelf portion bounded by a plurality of edges and includes an aperture 210 adapted to slidably receive an end of the rail member 206. In the embodiment shown in FIG. 2, each tray 208 can include an aperture 211 that is adapted to receive the additional rail member 207. The apertures 210, 211 can be spaced such that one receives an end of the rail member 206 and another simultaneously receives an end of the rail member 207. In an illustrative embodiment, a tray 208 can include the apertures 210, 211 within the shelf portion of the tray 208. The rail members 206, 207 can be coupled to the extensions 216, 217, and the apertures 210, 211 can be adapted to slide along the rail members 206, 207 after receiving ends of the rail members 206, 207 that are distal from the extensions 216, 217. Knobs 214, 215 or other elements sized larger than the first apertures 210, 211 of each tray 208 can be coupled to the distal ends of the rail members 206, 207 to prevent each tray 208 from unintentionally sliding off the distal ends of the rail member 206, 207.

In addition, each tray 208 can include additional apertures that are adapted to receive locking elements 212, 213 that can be tightened against the rail members 206, 207 to hold the tray 208 at a particular position along the rail members 206, 207. In one embodiment, the additional apertures can be substantially perpendicular to the apertures 210, 211 and can extend through edges of a tray 208. The locking elements 212, 213 can also be loosened to unsecure the tray 208 from its position, such that it can be moved to a different position along the rail members 206, 207 or removed from the rail members 206, 207. Each tray 208 is adapted to support an external device coupled to one or more servers housed in the server rack chassis 202 when the tray 208 is held at a position along the rail members 206, 207. Particular embodiments of the trays 208 are illustrated further in FIGS. 3 and 4.

FIG. 3 illustrates particular embodiments of aspects of a system to support external devices in relation to a server rack. A tray 308 includes a shelf portion 302 and a plurality of edges 304. A ring 310 is coupled to or integrated with at least one edge 304 the tray 308. The ring 310 bounds an aperture that is sized to receive a rail member 306, such that the ring 310 can slide along the rail member 306. The ring 310 also includes an additional aperture 313 that is adapted to receive a locking element, such as the adjustable screw 312. The additional aperture 312 communicates with the aperture bounded by the ring 310, such that the adjustable screw 312 can be tightened against the rail member 306 to hold the tray 308 at a position along the rail member 306.

FIG. 4 illustrates additional particular embodiments of aspects of a system to support external devices in relation to a server rack. A tray 408 includes a shelf portion 402 and a plurality of edges 404. The shelf portion 402 includes an aperture 410 that is sized to receive a rail member 406, such that the tray 408 can slide along the rail member 406. The tray 408 also includes an additional aperture 413 that is adapted to receive a locking element, such as the adjustable screw 412. The additional aperture 412 can penetrate an edge 404 of the tray 408 and communicates with the aperture 410, such that the adjustable screw 412 can be tightened against the rail member 406 to hold the tray 408 at a position along the rail member 406.

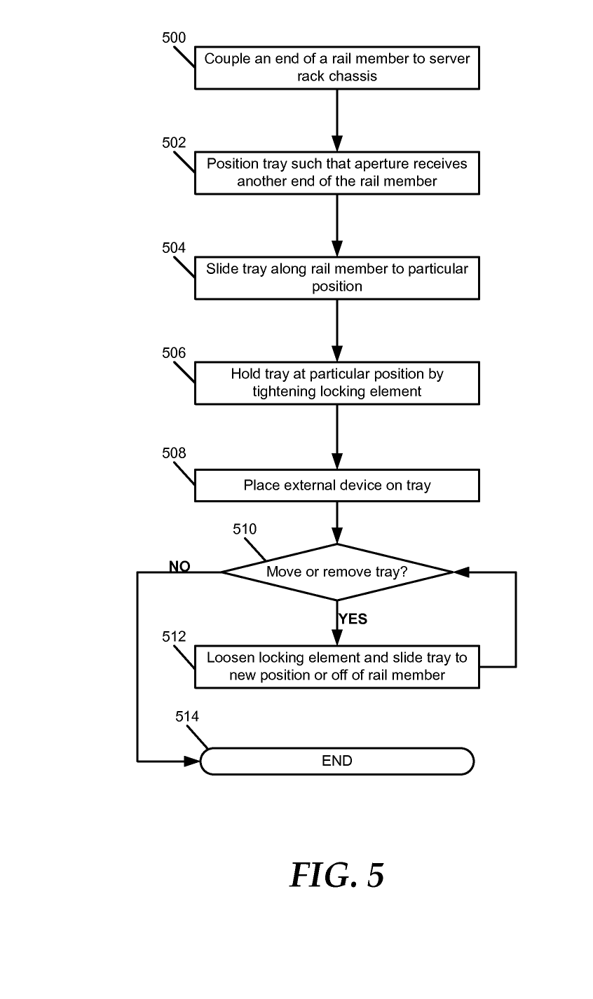

FIG. 5 is a flow diagram illustrating a particular embodiment of a method of supporting external devices in relation to a server rack. At block 500, an end of a rail member is coupled to a server rack chassis. The rail member is substantially parallel to a substantially vertical edge extending along a height of the server rack chassis when the rail member is coupled to the server rack chassis. Moving to block 502, a tray is positioned such that an aperture of the tray slidably receives another end of the rail member. Proceeding to block 504, the tray is slid to a particular position along the rail member. Continuing to block 506, the tray is held at the particular position by tightening a locking element against the rail member.

Advancing to block 508, an external device can be placed on the tray when the tray is held at the particular position along the rail member. At decision node 510, it can be determined whether the tray is to be moved to a new position or removed from the rail member. If the tray is to be moved or removed, the method moves to block 512, and the locking element can be loosened, allowing the tray to be moved or removed. If the tray is moved to a new position, the locking element can be re-tightened to hold the tray at the new position. If the tray is to be removed, the tray can be disengaged from the rail member by moving the aperture beyond the end of the rail member that was initially received by the aperture. In one embodiment, a knob sized to prevent the tray from being removed from the rail member can be removed from the rail member before removing the tray from the rail member. The method terminates at 514.

Many different aspects and embodiments are possible. Some of those aspects and embodiments are described below. After reading this specification, skilled artisans will appreciate that those aspects and embodiments are only illustrative and do not limit the scope of the present invention.

In a first aspect, a system to support external devices in relation to a server rack includes a server rack chassis having a plurality of sides, each side having a pair of substantially vertical edges extending along a height of the server rack chassis. The system also includes a rail member having a first end coupled to the server rack chassis. The rail member is substantially parallel to the substantially vertical edges when the first end of the rail member is coupled to the server rack chassis. The system also includes a tray comprising a first aperture adapted to slidably receive a second end of the rail member.

In an embodiment of the first aspect, the tray comprises a shelf portion bounded by a plurality of edges. The tray can include a ring coupled to at least one edge of the tray, the ring bounding the first aperture. Further, the ring can include a second aperture communicating with the first aperture, where the second aperture is sized to receive a locking element. The locking element can be adapted to hold the tray at a position along the rail member when the locking element is inserted through the second aperture and tightened against the rail member. The locking element can include an adjustable screw.

In another embodiment of the first aspect, the shelf portion of the tray can include the first aperture. The tray can include a second aperture extending through one of the plurality of edges and communicating with the first aperture. The second aperture can be sized to receive a locking element. The locking element can be adapted to hold the tray at a position along the rail member when the locking element is inserted through the second aperture and tightened against the rail member.

In a further embodiment of the first aspect, a knob can be coupled to the second end of the rail member. The knob can be sized such that the tray cannot be removed from the rail member when the knob is coupled to the second end of the rail member.

In an additional embodiment of the first aspect, the tray can be adapted to support an external device communicating with one or more servers housed in the server rack when the tray is held at a position along the rail member.

In a second aspect, system to support external devices in relation to a server rack includes a rail member having a first end adapted to be coupled to a server rack chassis, such that the rail member is substantially parallel to a substantially vertical edge extending along a height of the server rack chassis when the first end of the rail member is coupled to the server rack chassis. The system also includes a tray comprising a first aperture adapted to slidably receive a second end of the rail member, the tray adapted to support at least one external device when the tray is held at a position along the rail member.

In an embodiment of the second aspect, the tray can include a second aperture communicating with the first aperture. The tray can be held at the position along the rail member when an adjustable screw is inserted through the second aperture and is tightened against the rail member.

In another embodiment of the second aspect, a knob can be coupled to an end of the rail member. The knob can be sized such that the tray cannot be removed from the rail member when the knob is coupled to the end of the rail member.

In a further embodiment of the second aspect, the system can include a second rail member coupled to the server rack chassis. The tray can include a third aperture adapted to slidably receive the second rail member when the first aperture slidably receives the first rail member. The tray can include a fourth aperture communicating with the third aperture. The tray can be held at the position when a second adjustable screw is inserted through the fourth aperture and is tightened against the second rail member.

In an additional embodiment of the second aspect, the at least one external device includes an external CD drive, an external DVD drive, an external floppy drive, an external hard drive, an input device, a monitor, or any combination thereof.

In a third aspect, a method of supporting an external device communicating with a device housed in a server rack includes coupling a first end of a rail member to a server rack chassis. The rail member is substantially parallel to a substantially vertical edge extending along a height of the server rack chassis when the first end of the rail member is coupled to the server rack chassis. The method also includes sliding a tray to a position along the rail member after a first aperture of the tray slidably receives a second end of the rail member. The method also includes placing at least one external device on the tray when the tray is held at a position along the rail member.

In an embodiment of the third aspect, the method can include disengaging the tray from the rail member by moving the first aperture of the tray away from the first end of the rail member and beyond the second end of the rail member. A knob coupled to the second end of the rail member can be removed before disengaging the tray from the rail member, where the knob prevents the first aperture of the tray from moving beyond the second end of the rail member.

In another embodiment of the third aspect, the method can include holding the tray at a position along the rail member by inserting a locking element through a second aperture of the tray and tightening the locking element against the rail member. The second aperture of the tray can communicate with the first aperture of the tray.

In a further embodiment of the third aspect, the method can include loosening the locking element, sliding the tray to a second position along the rail member, and re-tightening the locking element to hold the tray at the second position.

Note that not all of the activities described above in the general description or the examples are required, that a portion of a specific activity may not be required, and that one or more further activities may be performed in addition to those described. Still further, the order in which activities are listed are not necessarily the order in which they are performed.

The specification and illustrations of the embodiments described herein are intended to provide a general understanding of the structure of the various embodiments. The specification and illustrations are not intended to serve as an exhaustive and comprehensive description of all of the elements and features of apparatus and systems that use the structures or methods described herein. Many other embodiments may be apparent to those of skill in the art upon reviewing the disclosure. Other embodiments may be used and derived from the disclosure, such that a structural substitution, logical substitution, or another change may be made without departing from the scope of the disclosure. Accordingly, the disclosure is to be regarded as illustrative rather than restrictive.

Certain features are, for clarity, described herein in the context of separate embodiments, may also be provided in combination in a single embodiment. Conversely, various features that are, for brevity, described in the context of a single embodiment, may also be provided separately or in any subcombination. Further, reference to values stated in ranges includes each and every value within that range.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

The above-disclosed subject matter is to be considered illustrative, and not restrictive, and the appended claims are intended to cover any and all such modifications, enhancements, and other embodiments that fall within the scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A system to support external devices in relation to a server rack, the system comprising:
a server rack chassis having a plurality of sides, each side having a pair of substantially vertical edges extending along a height of the server rack chassis;
a rail member having a first end coupled to the server rack chassis, wherein the rail member is substantially parallel to the substantially vertical edges when the first end of the rail member is coupled to the server rack chassis; and
a tray comprising a first aperture adapted to slidably receive a second end of the rail member.

2. The system of claim 1, wherein the tray comprises a shelf portion bounded by a plurality of edges.

3. The system of claim 2, wherein the tray comprises a ring coupled to at least one edge of the tray, the ring bounding the first aperture.

4. The system of claim 3, wherein:
the ring includes a second aperture communicating with the first aperture, the second aperture sized to receive a locking element; and
the locking element is adapted to hold the tray at a position along the rail member when the locking element is inserted through the second aperture and tightened against the rail member.

5. The system of claim 4, wherein the locking element comprises an adjustable screw.

6. The system of claim 2, wherein the shelf portion includes the first aperture.

7. The system of claim 6, wherein:
the tray includes a second aperture extending through one of the plurality of edges and communicating with the first aperture, the second aperture sized to receive a locking element; and
the locking element is adapted to hold the tray at a position along the rail member when the locking element is inserted through the second aperture and tightened against the rail member.

8. The system of claim 1, further comprising a knob coupled to the second end of the rail member, the knob sized such that the tray cannot be removed from the rail member when the knob is coupled to the second end of the rail member.

9. The system of claim 1, wherein the tray is adapted to support an external device communicating with one or more servers housed in the server rack when the tray is held at a position along the rail member.

10. A system to support external devices in relation to a server rack, the system comprising:
a rail member having a first end adapted to be coupled to a server rack chassis, such that the rail member is substantially parallel to a substantially vertical edge extending along a height of the server rack chassis when the first end of the rail member is coupled to the server rack chassis; and
a tray comprising a first aperture adapted to slidably receive a second end of the rail member, the tray adapted to support at least one external device when the tray is held at a position along the rail member.

11. The system of claim 1O, wherein the tray includes a second aperture communicating with the first aperture and wherein the tray is held at the position along the rail member when an adjustable screw is inserted through the second aperture and is tightened against the rail member.

12. The system of claim 10, further comprising a knob coupled to the second end of the rail member, the knob sized such that the tray cannot be removed from the rail member when the knob is coupled to the second end of the rail member.

13. The system of claim 10, comprising a second rail member coupled to the server rack chassis and wherein the tray includes a third aperture adapted to slidably receive the second rail member when the first aperture slidably receives the first rail member.

14. The system of claim 13, wherein the tray further comprises a fourth aperture communicating with the third aperture and wherein the tray is held at the position when a second adjustable screw is inserted through the fourth aperture and is tightened against the second rail member.

15. The system of claim 10, wherein the at least one external device comprises an external CD drive, an external DVD drive, an external floppy drive, an external hard drive, an input device, an output device, or any combination thereof.

16. A method of supporting an external device communicating with a device housed in a server rack, the method comprising:
coupling a first end of a rail member to a server rack chassis, wherein the rail member is substantially parallel to a substantially vertical edge extending along a height of the server rack chassis when the first end of the rail member is coupled to the server rack chassis;
sliding a tray to a position along the rail member after a first aperture of the tray slidably receives a second end of the rail member; and
placing at least one external device on the tray when the tray is held at a position along the rail member.

17. The method of claim 16, further comprising disengaging the tray from the rail member by moving the first aperture of the tray away from the first end of the rail member and beyond the second end of the rail member.

18. The method of claim 17, further comprising removing a knob coupled to the second end of the rail member before disengaging the tray from the rail member, wherein the knob prevents the first aperture of the tray from moving beyond the second end of the rail member.

19. The method of claim 16, further comprising holding the tray at a position along the rail member by inserting a locking element through a second aperture of the tray and tightening the locking element against the rail member, wherein the second aperture of the tray communicates with the first aperture of the tray.

20. The method of claim 19, further comprising:
loosening the locking element;
sliding the tray to a second position along the rail member; and
re-tightening the locking element to hold the tray at the second position.
